(19) United States
(12) Patent Application Publication
(10) Pub. No.: US 2010/0277231 A1
(43) Pub. Date: Nov. 4, 2010

(54) FILTERING ON CURRENT MODE DAISY CHAIN INPUTS

(75) Inventors: Christopher Peter HURRELL, Cookham (GB); Colin MCINTOSH, Hants (GB); Colin PRICE, Berks (GB); Jeremy GORBOLD, Newbury (GB); Mahesh K. MADHAVAN, Kerala (IN); Abhishek AGRAWAL, West Bengal (IN)

Correspondence Address: KENYON & KENYON LLP, 1500 K STREET, NW, WASHINGTON, DC, 20005-1257, US

(73) Assignee: ANALOG DEVICES, INC., Norwood, MA (US)

(21) Appl. No.: 12/719,481

(22) Filed: Mar. 8, 2010

Related U.S. Application Data
(60) Provisional application No. 61/174,710, filed on May 1, 2009.

(51) Int. Cl. H01L 25/00

(52) U.S. Cl. 327/564

(57) ABSTRACT

Embodiments may include a data receiver having input for a current signal. The data receiver may further include a current generator to generate a reference current for comparison against the input current signal. The data receiver may also include a data converter having an input coupled to an intermediate node of the data receiver, the data converter comprising a plurality of cascaded stages with intermediate nodes among the stages.

### CROSS-REFERENCE TO RELATED APPLICATIONS

This application claims priority under 35 U.S.C. §119 to U.S. Provisional Patent Application No. 61/174,710, filed May 1, 2009 and entitled “Improved Filtering On Current Mode Daisy Chain Inputs,” which is herein incorporated by reference in its entirety.

This disclosure is related to U.S. patent application Ser. No. 12/011,615, filed Jan. 28, 2008 and published Jul. 31, 2008 as U.S. publication No. 2008/0180106 (the '615 application), which is assigned to Analog Devices, Inc., the assignee of the present disclosure. The '615 application is incorporated into the present disclosure in its entirety.

### BACKGROUND

In many applications, rechargeable batteries are placed in series or in parallel in order to generate a desired output voltage. One such application is the use of batteries in hybrid- or fully-electric vehicles. Within these vehicles, a plurality of individual battery “cells” are arranged in order to build a battery stack having a desired output voltage. A large number of cells may be arranged in series such that, for example, the total potential difference developed across the battery stack is in the order of several hundred volts. Each cell typically only has a potential difference of a few, for example 2 to 4 volts, developed across it. Although the cells are similar, they are not identical, so repeated charging and discharging cycles may cause the voltage developed across some cells to be different than voltages developed across other cells. Ideally, the voltage across each individual cell, or at least small groups of cells, would be monitored such that the cells could be temporarily removed from a charging process if their terminal voltage gets too high or alternatively, if the cell temperature becomes unduly elevated. It is also possible to preferentially discharge cells to reduce their voltage. While it is feasible to build a single battery monitoring apparatus that can operate across the entire voltage range, for example 0 to 400 volts developed across a stack, this tends to be an expensive option.

Accordingly, there is a need for a battery monitoring system where each battery monitor can monitor the operating parameters of a single cell or a group of cells in a battery stack. Furthermore, there is a need for a method and system for communicating between each of the battery monitors and a method and system for reducing the effects of electro-magnetic corruption (EMC) on the system.

### BRIEF DESCRIPTION OF THE DRAWINGS

FIG. 1 illustrates an exemplary battery stack and battery monitoring system;

FIG. 2 illustrates an exemplary data transmitter and data receiver in accordance with one embodiment of the present invention;

FIG. 3A illustrates another exemplary data transmitter and data receiver in accordance with one embodiment of the present invention;

FIG. 3B illustrates exemplary signals at different stages of the data receiver illustrated in FIG. 3A;

FIG. 4 illustrates an exemplary data receiver in accordance with another embodiment of the present invention;

FIG. 5 illustrates yet another exemplary data receiver in accordance with another embodiment of the present invention.

### DETAILED DESCRIPTION

Embodiments of the present invention may include a data receiver having an input for a current signal. The data receiver may further include a current generator to generate a reference current for comparison against an input current signal. The data receiver may also include a data converter having an input coupled to an intermediate node of the data receiver, the data converter comprising a plurality of cascaded stages with intermediate nodes among the stages and a capacitive device coupled to at least one intermediate node among the stages. The data receiver may provide improved responses because it may drive a generated current into a received current before the received current enters the data conversion stages. The data receiver may limit responses of the data converter to current glitches because a capacitive device may be coupled on the current path at the output of at least one of the data conversion stages. The data receiver can further provide improved glitch response through tuning the capacitive device time response. The data receiver may also provide improved responses through conversion between the current and the voltage domains. Data conversion stages can also be current limited to provide output current responses within a prescribed current range. Moreover, data conversion stages can be voltage limited to provide voltage responses within a prescribed voltage range.

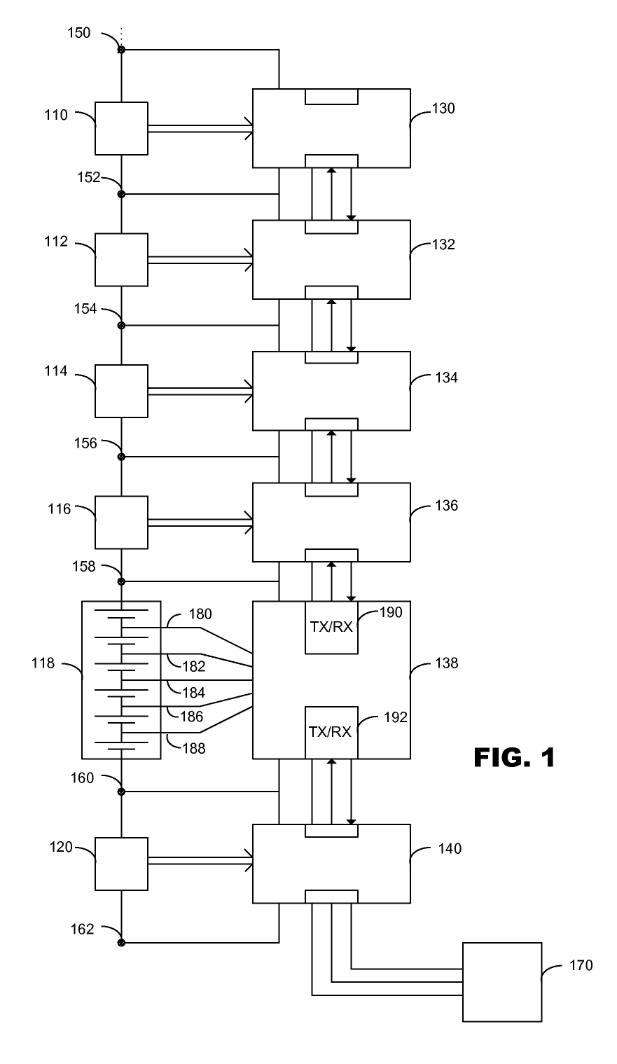

FIG. 1 illustrates an exemplary battery stack 100 including six groups of battery cells 110, 112, 114, 116, 118 and 120. Each of the groups of battery cells may be nominally identical, however, only the individual cells within the group 118 are individually drawn for ease of description. In this example, each group of battery cells comprises six individual battery cells; however, any number of individual battery cells is possible. Each group of battery cells may develop, for example, a potential of 25 volts across it when fully charged. A cathode of the first group 10 may be connected to a local ground. Accordingly, a voltage occurring at a first node 152 between the first group of cells 110 and the second group of battery cells 112 is approximately 25 volts compared to the ground. Similarly the voltage occurring at a second node 154 between the second group of battery cells 112 and the third group of cells 114 may be approximately 50 volts. The voltage occurring at a third node 156 may be 75 volts, the voltage occurring at a fourth node 158 may be 100 volts, the voltage occurring at node 160 may be 125 volts and the voltage occurring at node 162 may be 150 volts.

Each group of battery cells may be associated with a respective battery monitoring device, 130, 132, 134, 136, 138 or 140. Each battery monitor 130-140 may determine the voltage of its respective battery cell group, and may report the voltage value to a system controller 170. The battery monitors 130-140 may be provided in a so-called ‘daisy chain’ of groups in which data to be read from any given battery monitor (say, monitor 134) may be passed serially from each battery monitor to the next (134→136→138, etc.) until it reaches a battery monitor 140 at the end of the chain. Battery monitor 140 may pass the communicated data to a system controller 170.

Since the battery stack 100 may use multiple battery monitors rather than a single monitoring apparatus to monitor the entirety of the battery stack, the potential difference spanning across each battery monitor is reduced and as a result relatively inexpensive semiconductor fabrication processes can be used to fabricate integrated circuits capable of operating with the limited potential difference existing across the subunit within the battery stack.

Each battery monitoring device 130-140 can measure a plurality of parameters, including voltage potential across each individual cell or any combination of cells of its associated cell group. Further, the devices may also measure temperature. The voltage and/or temperature may be sent as a digital word to the system controller 170. As seen, for example, in FIG. 1, the battery monitoring device 138 may measure the voltage across nodes 158 and 160 to determine the voltage of the entire cell group or across any of the individual cells via nodes 158 and 160 and leads 180-188. Since each individual battery cell in each battery cell group can be measured independently, the system controller 170 can tailor the charge/discharge cycle for each individual battery cell based upon the present charge stored within the battery cell and/or the temperature of the battery cell.

Data can be read from battery monitors 130-140 from any position of the daisy chain and communicated to the system controller 170. Moreover, data may be transmitted from the system controller 170 to a battery monitor 130-140 at any position of the daisy chain. Thus, the system controller 170 can read or write data to any position of the daisy chain, and battery monitors at intermediate positions of the daisy chain may relay the communicated data from the source of the data to its destination.

Each battery monitoring device may have a pair of transceivers, for example transceivers 190 and 192, within battery monitoring device 138. Reliable communication between integrated circuits may be compromised by spurious electro-magnetic corruption (EMC), commonly, called “glitches” introduced between the integrated circuit. Glitches can cause a receiver to detect multiple spurious edges on data or clock inputs which causes data corruption. The data errors caused by glitches could be digitized by one of the transceivers and, if so, could be propagated throughout the remainder of a communication path as digital data. Accordingly, each transceiver may have an EMC reduction circuit to reduce or eliminate the influence of glitches in the system. Each of the transceivers 190 and 192 may include data receivers for receiving data.

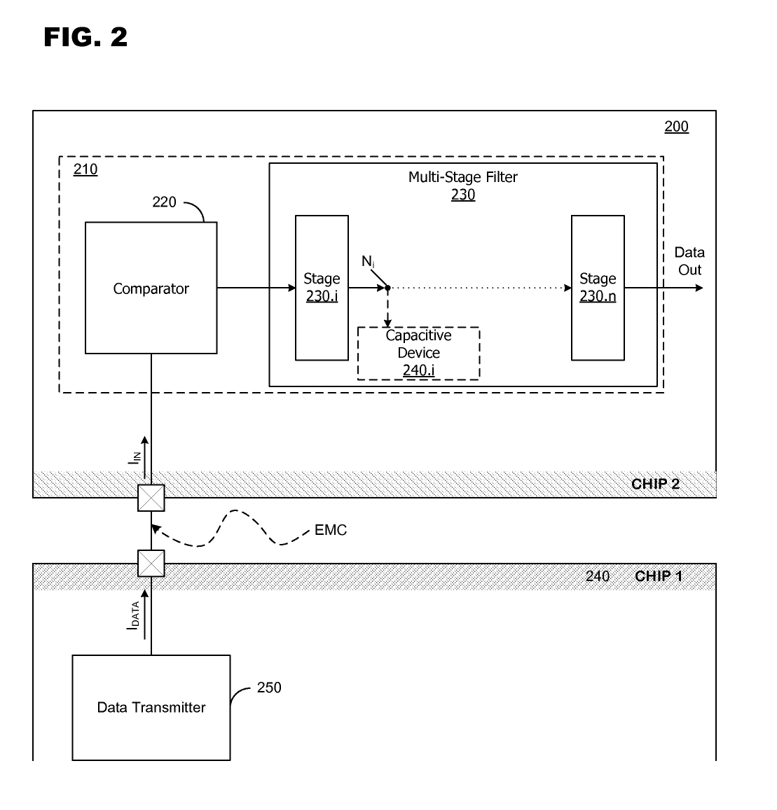

FIG. 2 illustrates a data receiver 200 including an EMC reduction circuit 210. The EMC reduction circuit may include a comparator 220 that may receive a data signal in the form of an input current I_{IN}. The input current I_{IN} may correspond to an output data current I_{DATA}, generated by a data transmitter 250 in battery monitor 240, subject to any EMC. The comparator may compare the input current I_{IN} to a reference current. If the input current I_{IN} is smaller than the reference current, a negative voltage potential may be output by the comparator 220. Conversely, if the input current I_{IN} is larger than the reference current, a positive voltage potential may be output by the comparator 220.

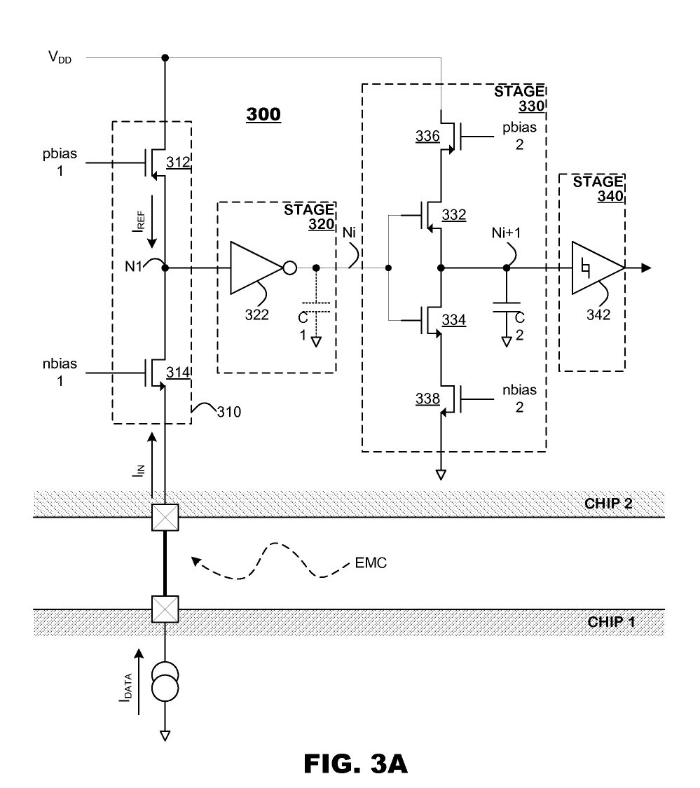

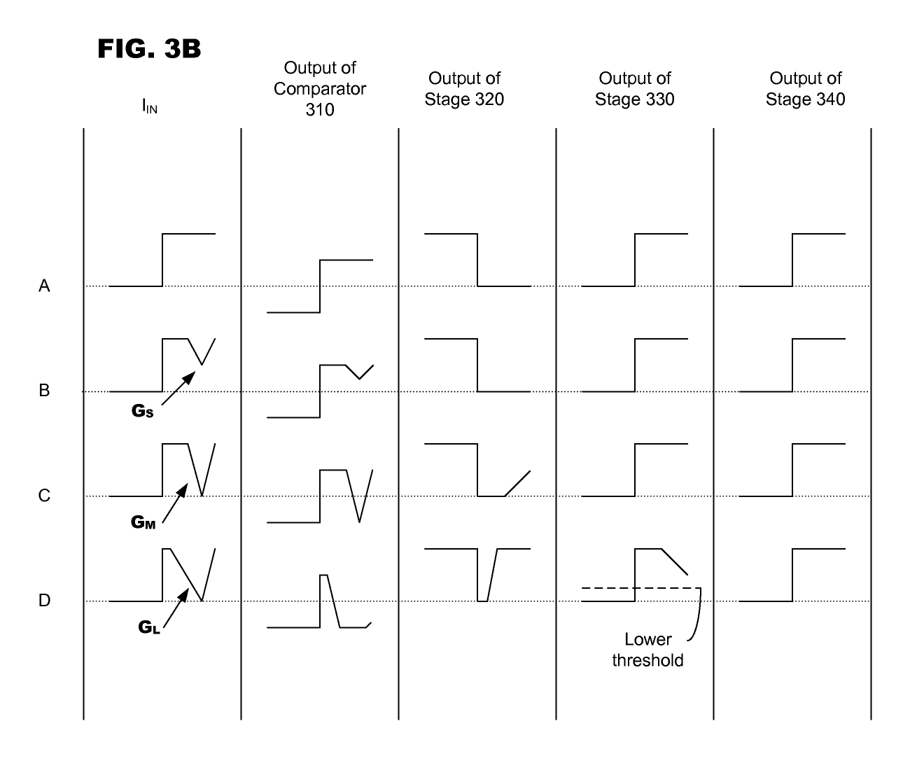

The output of the comparator 220 may be transmitted to a multi-stage data converter 230. The multi-stage data converter 230 illustrated in FIG. 3 has stages 1-n arranged in a cascade. The stages of the multi-stage data converter 230 may be simple circuits, such as a series of inverters, integrators, OR gates, NAND gates, Schmitt triggers, or the like. In order for the data signal to pass through the multi-stage data converter 230, each bit of the data signal should have a long enough duration to propagate through every stage of the multi-stage data converter 130. Each stage may be designed to have a longer propagation delay than a previous stage and/or have a different triggering point than previous stages. If the stage is, for example, an integrator, the input signal to the stage may be integrated over a predetermined period of time and the output of the stage may be based upon the integration.

Since glitches typically have a shorter duration than data present on the input signal, the glitches will generally not propagate through every stage of the multi-stage data converter 230. Accordingly, even if a glitch temporarily alters the output from the comparator 220 or even a stage of the multi-stage data converter 230, the data integrity of the input signal is maintained since the glitches will not generally propagate through every stage of the multi-stage data converter 230.

Each stage may have a corresponding capacitive device (e.g., capacitor 240.i) capacitively shorting the output of each stage to a ground potential. The capacitive device (e.g., capacitor 240.i) may provide further protection against glitches. The capacitive device may be a capacitor or a plurality of transistors providing a capacitive effect. Since capacitors resist a change in voltage, even if a glitch temporarily changes the output of a stage, the glitch in the output of the stage may not propagate to a next stage since the capacitive device will resist the change. Furthermore, the capacitors can be used to lengthen the propagation delay for certain types of logic gates. Optionally, a fuse (not shown) may be placed between the capacitive device and an intermediate node to provide for protection against large current spikes.

FIG. 3A illustrates another exemplary data receiver 300 including an EMC reduction circuit. The data receiver 300 may have an input 305 and may include a comparator 310. The comparator 310 may include a first transistor 312 and a second transistor 314 providing a reference current I_{REF} based upon a voltage potential V_{DD}, bias potentials P_{BIAS1} and N_{BIAS1} and the input current I_{IN}. The voltage potential V_{DD}, bias potentials P_{BIAS1} and N_{BIAS1} can be selected in such a manner such that when the binary information signal represented by IIN is in a first state, the resultant current (I_{REF}) will flow in a first direction (e.g., input to V_{DD}) and to flow in a second direction (e.g., V_{DD} to the input pin) when the binary information signal is in a second state. This resultant current induces a corresponding voltage at node N1 depending on the state of current signal I_{IN}. The bias potentials P_{BIAS1} and N_{BIAS1} may be individually, or in tandem, set to control the amount of current of I_{REF} or I_{IN} may respectively pass each of transistors 312 and 314, respectively.

The data receiver 300 may further include a first stage 320 as part of a multi-stage data converter. Stage 320 may include an inverter 322. Optionally, the stage 320 may also include capacitor C1 connected from the output of the inverter 322 to ground or a reference potential VSS. The input of the inverter may be connected to the output of a comparator, for example, node N1.

The data receiver 300 may include a second stage 330 as a stage of the multi-stage data converter. Second stage 330 may include a first pair of transistors 332 and 334 arranged as an inverter. Transistor 332 may be a p-channel MOSFET and transistor 334 may be an n-channel MOSFET. Transistors 332 and 334 may be biased transistors. A drain of transistor 332 may be connected to a source of transistor 334. The gates of transistors 332 and 334 may be connected to the output of first stage 320. The second stage 330 may include a second pair of transistors 336 and 338 formed to limit current through transistors 332 and 334, respectively. The source terminal of transistor 336 may be connected to a drain of transistor 332. A drain terminal of transistor 336 may be connected to the reference voltage V_{DD}. The drain terminal of transistor 338 may be connected to a source terminal of transistor 334, while a source terminal of transistor 338 may be connected to ground or a reference voltage VSS. Optionally, the stage 330 may also include capacitor C2 connected from the output of the inverter (transistors 332 and 334) to ground.

The data receiver 300 may include a third stage 340 as a stage of the multi-stage data converter. The stage 340 may include a Schmitt triggered buffer 342. Optionally, the stage 340 may also include capacitor C3 connected from the output of the Schmitt triggered buffer 342 to ground at a node N3.

Operationally, the data receiver 300 may receive an input signal I_{IN} corresponding to a data signal, which may have been subject to EMC. The input signal I_{IN} may be received by the comparator 310 via input 305 at a source terminal of transistor 314. The comparator 310 may compare the input current I_{IN} to a reference current I_{REF}. As discussed above, when the information signal represented by I_{IN} is in a first state, a resultant current (I_{REF}) may flow in a first direction (e.g., from input 305 to reference voltage V_{DD}), and when the information signal is in a second state I_{REF} may flow in an opposite direction (e.g., reference voltage V_{DD} to the input pin). This resultant current may induce a corresponding voltage at node N1, which may be the input to stage 320 of the data receiver 300.

The voltage output by the comparator 310 is received at the input to inverter 322. The inverter 322 may inherently have a propagation delay at its output, so while transition occurs at the input to the inverter (either high to low or low to high) the change may be delayed at the output. The inverter 310 can be designed to have a longer or shorter propagation delay depending upon the amount of EMC the circuit may be expected to experience. The propagation delay may be increased by adding a capacitor, for example capacitor C1, between the output of the inverter 322 and ground or a reference potential V_{SS}. The propagation delay can be lengthened by increasing the size of the capacitor C1. The propagation delay can also be lengthened by decreasing a power supply voltage V_{DD} supplied to the inverter 322 by adding a resistor in the power supply path, a lower process transconductance parameter can be used, and/or a width/length ratio of the transistors can be decreased.

The output of first stage 320 may be transmitted to the input of transistors 332 and 334 in second stage 330, which are arranged as an inverter. Transistors 336 and 338 may be used to limit current of transistors 332 and 334, respectively. The bias potentials P_{BIAS2} and N_{BIAS2} may be individually, or in tandem, set to control the amount of current that may respectively passed by each of transistors 336 and 338, respectively. By limiting the current, a resultant potential across the inverter of second stage 330 may also be limited, and so discussed above, the propagation delay may be increased (i.e., by lowering a power supply voltage and/or raising the lower potential VSS to a non-zero value). Accordingly, the inverter represented in second stage 330 may be designed to have a longer propagation delay than the inverter 322 in second stage 330. Thus, a glitch which may have persisted long enough to change the output of first stage 320 may not persist long enough to change the output of the inverter in second stage 330. While only two inverters are illustrated in the data receiver 300 illustrated in FIG. 3A, any number of inverters, preferably added in pairs, may be used. Each inverter in the chain may be designed to have a longer propagation delay.

The output of the inverter arranged in second stage 330 may be output to a Schmitt triggered buffer 342 in third stage 340. If an odd number of inverter stages are used previously in the chain, an inverting Schmitt trigger could be used. Schmitt triggers are designed to have a persistent output. When the input to the Schmitt trigger is higher than a certain chosen threshold, the output is transitioned high. When the input is below another (lower) chosen threshold, the output is transitioned low. However, when the input is between the two, the output retains its current value. So, even if a glitch that obscures a signal transition persisted long enough to pass through the inverters in first stage 320 and second stage 330, the input to the Schmitt trigger would have to rise above the upper threshold or fall below the lower threshold before the output to the Schmitt trigger will change its output value. Accordingly, the EMC of the input signal is effectively removed from the input signal prior to further signal processing.

FIG. 3B illustrates the exemplary input signals I_{IN} and the effects each input signal may have on the stages of the data receiver 300. Exemplary input signal A illustrates an input signal without a glitch. As seen in FIG. 3B, the output of the comparator 310 may transition from a positive voltage to a negative voltage when I_{IN} becomes larger than some predetermined I_{REF}. The output of stage 320 inverts the signal, which is then inverted again in second stage 330. When the output of second stage 330 rises above an upper threshold of the Schmitt trigger 342 in third stage 340, the output of third stage 340 may transition from low to high.

Exemplary input signal B illustrates an input signal with a small glitch G_{S}. As seen in FIG. 3B, the glitch temporarily alters the output of comparator 310. However, in this example, the glitch G_{S} did not persist long enough to alter the output of stage 320, or any of the other stages.

Exemplary input signal C illustrates an input signal with a larger glitch G_{M}. As seen in FIG. 3B, the glitch G_{M} temporarily alters the output of comparator 310 and affects the output of stage 320. However, in this example, the glitch G_{M} did not persist long enough to alter the output of stage 330, and as a result, any of the other stages.

Exemplary input signal D illustrates an input signal with an even larger glitch G_{L}. As seen in FIG. 3B, the glitch G_{L} temporarily alters the output of comparator 310 and affects the output of stages 320 and 330. However, because the output of stage 330 may not fall below a predetermined lower threshold, and as a result, the output of stage 340 may remain unchanged.

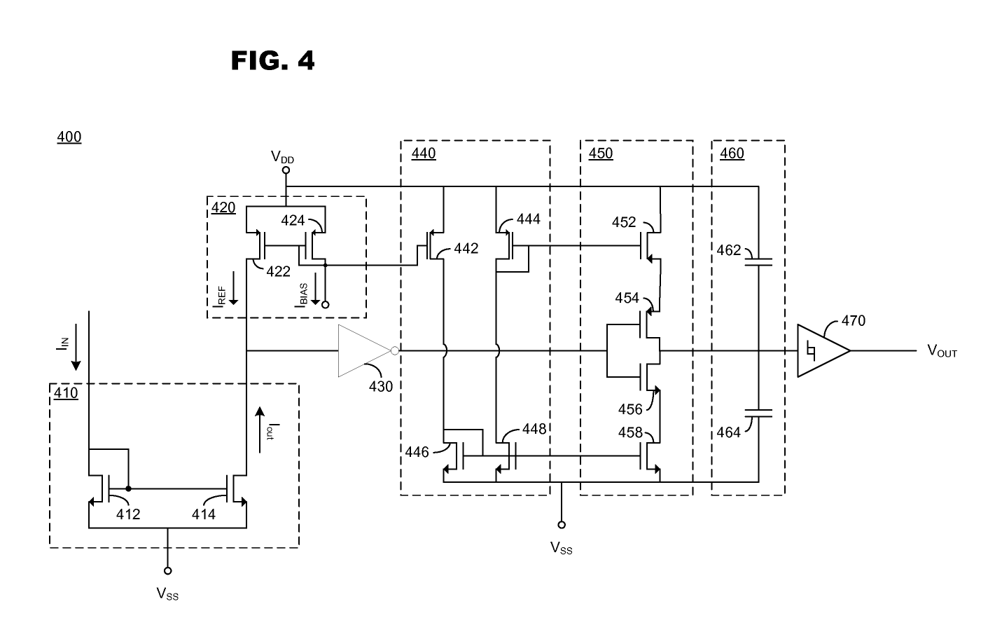

FIG. 4 illustrates another embodiment of a data receiver 400. The data receiver 410 may include a current mirror 410, which may include transistors 412 and 414 The current mirror 410 may receive an input signal IIN corresponding to an input data signal, subject to any EMC. The current mirror 410 attempts to mirror the input current signal, and outputs the current IOUT. The data receiver 400 may further include a reference current generator 420. The reference current generator may include transistors 422 and 424 arranged as a current mirror. The reference current generator may receiver a bias current IBIAS which is mirrored as and output as reference current IREF.

The reference current IREF output from the reference current generator 420 and the output current IOUT may both be fed into the input terminal of inverter 430. The bias current IBIAS may be selected such that when the data represented by the input signal IIN is in a first state a positive voltage is present at the input to the inverter and when the data represented by the input signal IIN is in a second state a negative voltage is present at the input to the inverter.

The output of inverter 430 may be fed into an input terminal of an inverter 450. The inverter 450 may include transistors 454 and 456. The transistor 454 and 456 may be arranged as an inverter. The inverter 450 may further include biasing transistors 452 and 458 which can bias a potential across the inverter to either lengthen or reduce the propagation delay of the inverter. The gate terminals of transistors 452 and 456 may be controlled by the output of a voltage bias generator 440.

The voltage bias generator 440 may include transistors 442, 444, 446, 448 arranged to form a current mirror. The source terminal of transistors 442 and 444 may be connected to reference voltage V_{DD}. The gate terminal of transistor 442 may be connected to the gate terminal and the drain of transistor 424 in the reference current generator 420. The drain of the 442 transistor may be connected to the drain and gate of the transistor 446, which is arranged as a current mirror with transistor 448. The drain and the gate of transistor 444 may be connected to the gate of biasing transistor 452 in the inverter 450. In addition, the drain and gate of transistor 444 is connected to the drain of transistor 448. The gates of both transistor 446 and transistor 448 are connected to the gate of biasing transistor 458 of the inverter 458.

In operation, transistor 442 of the voltage bias generator 440 is enabled by a reference signal from the reference current generator 420 that is applied to the gate of transistor 442. A current may flow through transistor 442. This current is mirrored through transistor 444 because of the current mirror arrangement of transistors 446 and 448. The current through transistor 444 results in a gate voltage of the transistor 444 being applied to the gate of biasing transistor 452, and similarly, the current through the transistor 448 results in a gate voltage of the transistor 448 being applied to the gate of biasing transistor 458. The voltages supplied by the voltage bias generator 440 may be proportional to the bias current I_{BIAS} that is mirrored from the reference current I_{REF}.

The output of inverter 450 may be connected to a capacitor network 460. The capacitor network 460 may include a capacitor 462 connecting the output of the inverter 450 to an upper potential VDD. The capacitor network 460 may further include a capacitor 464 connecting the output of the inverter 450 to a lower potential V_{SS}. The capacitors network 460 may be tuned to control the length of propagation delay of inverter 450.

The output of inverter 450 may further be connected to the input terminal of a Schmitt triggered buffer 470. As discussed above, an upper and lower threshold may be selected for the Schmitt triggered buffer 470 which will prevent the output of the Schmitt triggered buffer 470 from changing until the output of the inverter 450 rises above or falls below the respective thresholds.

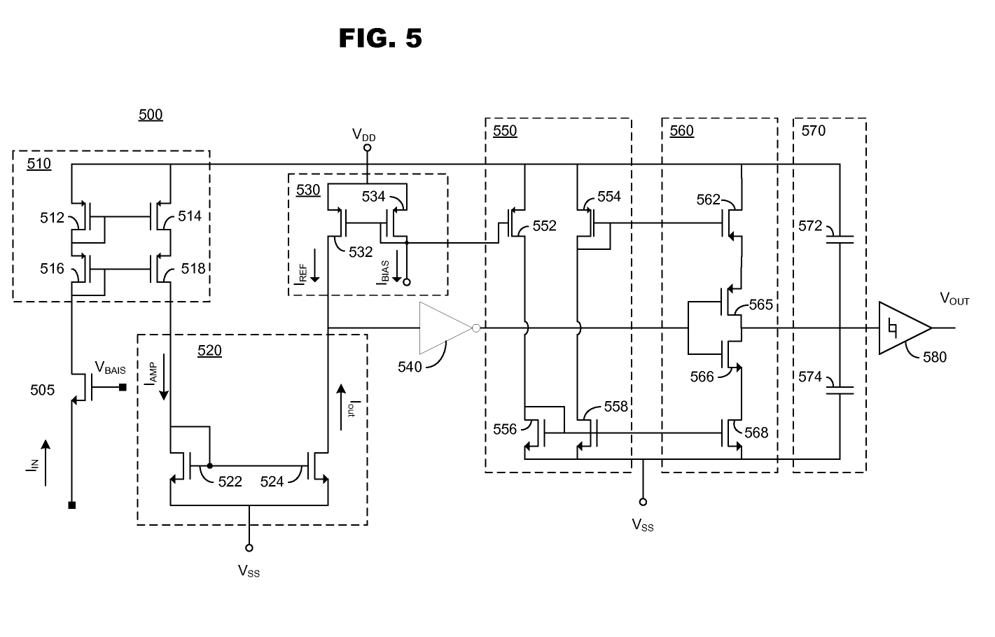

FIG. 5 illustrates yet another embodiment of a data receiver 500. The data receiver may include a current mirroring circuit 510, a voltage bias transistor V_{BIAS} and a capacitance module 570. The output of the current mirror circuit 510 may be an amplified current signal I_{AMP} that may be transmitted to the input of a current mirror 520.

Based on the bias voltage V_{BIAS} applied to the transistor 505, the input current signal I_{IN} provided to the current mirroring circuit 510 may be limited, which may also limit the effect of any glitches in the input current signal I_{IN}. The amplifying current mirroring circuit 510 may include two pairs of transistors 512, 514 and 516 and 518 arranged as current mirrors. Transistors 512 and 514 may be arranged as a first current mirror, and transistors 516 and 518 may be arranged as a second current mirror. The current mirroring circuit 510 provides an amplified current signal I_{AMP} that is input into the current mirror 520. The operation of the current mirror 520 is similar to the current mirror 410 of FIG. 4. A benefit of the arrangement of current mirroring circuit 510 is that it may reduce the effect of supply variations on the current that is mirrored. The transistor 505 may also reduce the effect of input variations on the I_{IN} node by applying the bias voltage V_{BIAS} on the gate of transistor 505. The current mirroring circuit 510 and the transistor 505 may thereby reduce the effects of voltage variations, whether on the supply or the input.

The capacitance module 570 may provide yet another stage for introducing a propagation delay into the input circuit to further mitigate any errors that may be caused by glitches present on the input signal passed by the previous stages 510-560.

Similar as those described in conjunction with FIG. 4, the data receiver 500 may further include a current mirror 520, a reference current generator 530, an inverter 540 a voltage bias generator 550 and inverter 560 and a Schmitt triggered buffer 580.

Several embodiments of the invention are specifically illustrated and/or described herein. However, it will be appreciated that modifications and variations of the invention are covered by the above teachings and within the purview of the appended claims without departing from the spirit and intended scope of the invention.

We claim:

1. An integrated circuit comprising:
a data receiver having input for a current signal, the data receiver having a current generator to generate a reference current for comparison against the input current signal;
a data converter having an input coupled to an intermediate node of the data receiver, the data converter comprising a plurality of cascaded data converter stages with intermediate nodes among the data converter stages.

2. The integrated circuit of claim 1, wherein at least one of the data converter stages is an integrator.

3. The integrated circuit of claim 1, wherein at least one of the data converter stages is an inverter.

4. The integrated circuit of claim 1, wherein at least one of the data converter stages is a current-limited inverter having a pair of current generators to generate a first current limit and a second current limit.

5. The integrated circuit of claim 4, wherein the current generators are current mirrors.

6. The integrated circuit of clam 1, wherein at least one of the data converter stages is a Schmitt-triggered buffer.

7. The integrated circuit of claim 1, wherein the data receiver further comprises two biased transistors extending from a first voltage reference to a second voltage reference, and the data converter input is coupled to an intermediate node between the biased transistors.

8. The integrated circuit of claim 1, wherein the current generator is a current mirror.

9. The integrated circuit of claim 1, further comprising:
a capacitive device coupled to at least one intermediate node among the data converter stages.

10. The integrated circuit of claim 9, wherein the capacitive device limits response of the data converter to glitches on the input current signal

11. The integrated circuit of claim 9, wherein the capacitive device comprises a plurality of capacitors.

12. The integrated circuit of claim 9, wherein the capacitive device comprises a plurality of transistors.
